(19) United States
(12) Patent Application Publication
(10) Pub. No.: US 2017/0102109 A1
(43) Pub. Date: Apr. 13, 2017

(54) WALL-HANG APPARATUS OF DISPLAY DEVICE, AND DISPLAY DEVICE

(71) Applicants: Le Holdings(Beijing)Co., Ltd., Beijing (CN); LE SHI ZHI XIN ELECTRONIC TECHNOLOGY (TIAN JIN) LIMITED, Tianjin (CN)

(72) Inventors: Cong ZHANG, Tianjin (CN); Shiming QING, Tianjin (CN); Feng SUN, Tianjin (CN)

(21) Appl. No.: 15/222,481

(22) Filed: Jul. 28, 2016

Related U.S. Application Data
(63) Continuation of application No. PCT/CN2016/081911, filed on May 12, 2016.

(30) Foreign Application Priority Data
Oct. 8, 2015 (CN) 201520774737.9

(51) Int. Cl. F16M 13/02; H05K 7/14

(52) U.S. Cl. CPC F16M 13/02; H05K 7/14

(57) ABSTRACT

The disclosure provides a wall-hang apparatus of a display device, and a display device. The wall-hang apparatus of a display device includes: a wall fixture fixed to a wall, a display device fixture fixed to a display device body, and a bolt, wherein the display device fixture is hung on the wall fixture; and the wall fixture is provided with a first pin hole, the display device fixture is provided with a second pin hole positioned opposite to the first pin hole, and the bolt is inserted into the first pin hole and the second pin hole. With the wall-hang apparatus of a display device according to the disclosure, the reliability of hanging the display device on a wall securely can be improved.

### CROSS-REFERENCE TO RELATED APPLICATIONS

This application is a continuation of International Application No. PCT/CN2016/081911, filed on May 12, 2016, which claims the benefit of Chinese Patent Application No. 201520774737.9, filed on Oct. 8, 2015, both of which are hereby incorporated by reference in their entireties.

### TECHNICAL FIELD

The present disclosure relates to the field of installing a display device, and particularly to a wall-hang apparatus of a display device, and a display device.

### BACKGROUND

A hang bracket of a TV set is a peripheral apparatus of the TV set designed to hang a flat-screen TV set, a liquid crystal TV set, etc., on a wall, and widely applied at home, in an office, a meeting room, an exhibition hall, a hotel, an airport, a railway station, a hospital, a bus stop, a shopping mall, and other places.

At preset, the TV set is generally installed on the hang bracket simply by hanging the TV set on the hang bracket, but if the TV set is touched unintentionally by an external force, then the TV set may accidentally fall down from the hang bracket, thus damaging the TV set and even hurting a person.

### SUMMARY

Embodiments of the disclosure provide a wall-hang apparatus of a display device, and a display device so as to improve the reliability of hanging the display device body on a wall securely.

An embodiment of the disclosure provides a wall-hang apparatus of a display device, the wall-hang apparatus includes: a wall fixture fixed to a wall, a display device fixture fixed to a display device body, and a bolt, wherein the display device fixture is hung on the wall fixture; and the wall fixture is provided with a first pin hole, the display device fixture is provided with a second pin hole positioned opposite to the first pin hole, and the bolt is inserted into the first pin hole and the second pin hole.

In one embodiment, the bolt is provided with a bolt neck, and a bolt head and a bolt tail, both of which are parallel to each other, and connected by the bolt neck.

In one embodiment, a bolt pull rope is fixed on the bolt tail and the bolt neck of the bolt.

In one embodiment, the wall fixture is arranged horizontally, and the display device fixture is arranged vertically.

In one embodiment, the number of display device fixtures is at least two; and the number of bolts is at least two, and each of the bolts is arranged corresponding to one of the display device fixtures.

In one embodiment, the wall fixture is provided with a hang plate, and the display device fixture is provided with a hang hook hung on the hang plate.

In one embodiment, the hang plate is provided with a hang limit opening in which the hang hook is hung.

The display device can be installed using the wall-hang apparatus of the display device according to the embodiments of the disclosure by firstly fixing the display device body to the display device fixture, then hanging the display device fixture to the wall fixture, and finally inserting the bolt into the first pin hole and the second pin hole, so that the display device body and the display device fixture being fixed in position by the bolt will not fall down easily from the wall fixture even if an external force is applied thereto, and thus the wall-hang apparatus of the display device according to the embodiment of the disclosure can be more secure and reliable than the prior art.

An embodiment of the disclosure further provides a display device including a display device body, and the wall-hang apparatus according to any one of the technical solutions above. The displaying device using the wall-hang apparatus will not fall down easily from the wall-hang apparatus even if an external force is applied thereto, so the display device can be installed highly reliably.

### BRIEF DESCRIPTION OF THE DRAWINGS

In order to make the technical solutions according to the embodiments of the disclosure or in the prior art more apparent, the drawings to which a description of the embodiments or the prior art refers will be briefly introduced below, and apparently the drawings to be described below are merely illustrative of some of the embodiments of the disclosure, and those ordinarily skilled in the art can derive from these drawings other drawings without any inventive effort. In the drawings:

FIG. 1 is a schematic diagram of a wall-hang apparatus which is not assembled according to an embodiment of the disclosure;

FIG. 2 is a schematic diagram of the wall-hang apparatus which has been assembled according to an embodiment of the disclosure; and

FIG. 3 is a schematic diagram of the wall-hang apparatus on which a display device body is installed according to an embodiment of the disclosure.

### REFERENCE NUMERALS

1—Wall fixture;

2—Display device fixture;

3—Bolt;

4—Bolt pull rope;

5—Screw;

6—Hang-limit opening;

7—Display device body

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure, and apparently the embodiments described below are only a part but not all of the embodiments of the disclosure. Based upon the embodiments here of the disclosure, all the other embodiments which can occur to those skilled in the art without any inventive effort shall fall into the scope of the disclosure.

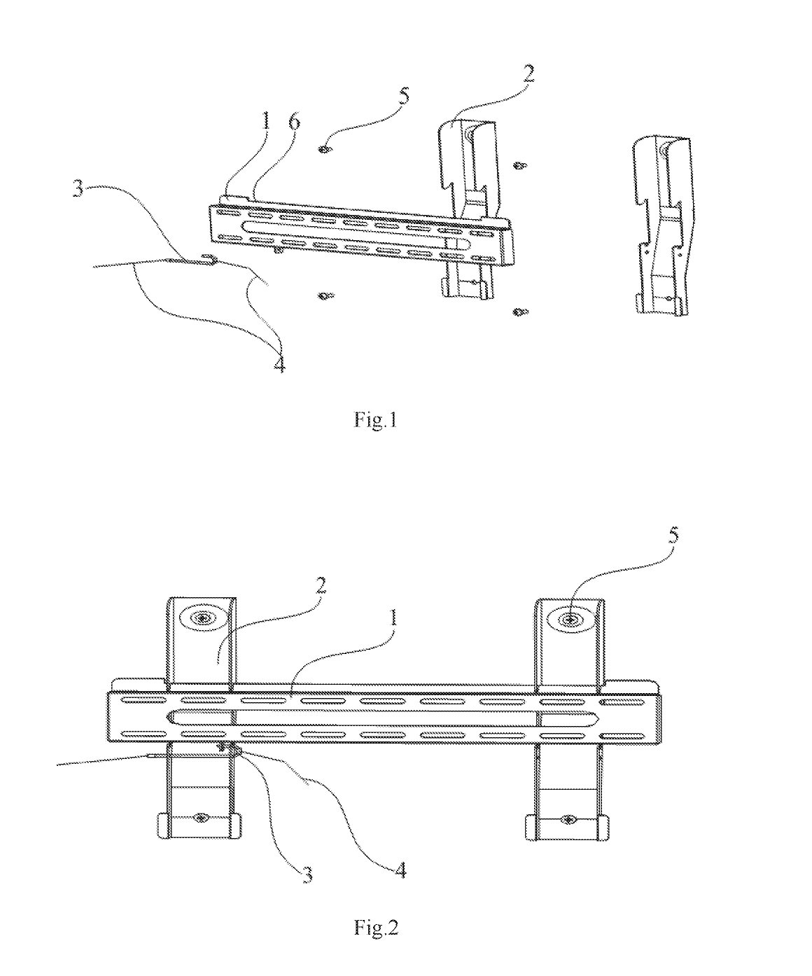

As illustrated in FIG. 1, a wall-hang apparatus of a display device according to an embodiment of the disclosure includes a wall fixture 1 fixed to a wall, a display device fixture 2 fixed to a display device body, and a bolt 3, where the display device fixture 2 is hung on the wall fixture 1; and the wall fixture 1 is provided with a first pin hole, the display device fixture 2 is provided with a second pin hole positioned opposite to the first pin hole, and the bolt 3 is inserted into the first pin hole and the second pin hole.

The wall-hang apparatus of a display device according to the embodiment of the disclosure can be applicable at home, in an office, a meeting room, an exhibition hall, a hotel, an airport, a railway station, a hospital, a bus stop, a shopping mall, and other places.

The display device body will not be limited to any particular type, but can be a TV set, a computer display, a display screen, etc., for example.

The display device can be hung on the wall-hang apparatus of a display device according to the embodiment of the disclosure by firstly fixing the display device body to the display device fixture, then hanging the display device fixture to the wall fixture, and finally inserting the bolt into the first pin hole and the second pin hole, so that the display device body and the display device fixture being fixed in position by the bolt will not fall down easily from the wall fixture even if an external force is applied thereto, and thus the wall-hang apparatus of the display device according to the embodiment of the disclosure can be more secure and reliable than the prior art.

The bolt will not be limited to any particular shape, but can be L-shaped, U-shaped, or shaped straight, for example, and in a technical solution according to an embodiment of the disclosure, the bolt 3 as illustrated in FIG. 1 is provided with a bolt neck, and a bolt head and a bolt tail, both of which are parallel to each other, where the bolt head is shorter so that it can be inserted conveniently into the pin holes, and the bolt head and the bolt tail are connected by the bolt neck.

As illustrated in FIG. 2, in a preferred embodiment of the disclosure, there is a bolt pull rope 4 fixed on the bolt head and the bolt neck of the bolt. The bolt can be inserted into the pin holes simply by aligning the bolt with the first pin hole and the second pin hole, and pulling the bolt pull rope fixed on the bolt nail; and alike the bolt can be pulled out of the pin holes simply by pulling the bolt pull rope fixed on the bolt neck.

As illustrated in FIG. 2, in a preferred technical solution according to an embodiment of the disclosure, the display device can be installed by arranging the wall fixture 1 horizontally and the display device fixture 2 vertically.

The number of display device fixtures to which the display device body is fixed will not be limited to only one, but can be two or more, and as illustrated in FIG. 2, there are two display device fixtures in a technical solution according to an embodiment of the disclosure.

If there are two or more display device fixtures, then there may be two or more bolts, each of which is arranged corresponding to one of the display device fixtures, and each of which can be inserted into the pin hole on the display device fixture, and the pin hole on the wall fixture, corresponding thereto.

In a technical solution according to an embodiment of the disclosure, the wall fixture is provided with a hang plate, the display device fixture is provided with a hang hook hung on the hang plate, and the hang plate is located on an upper part of the wall fixture, so that the hang hook and the hang plate can be structured to be assembled conveniently to thereby enhance the stability of the display device being installed.

As illustrated in FIG. 1, in a technical solution according to an embodiment of the disclosure, the hang plate is provided with a hang limit opening 6 in which the hang hook is hung. As illustrated in FIG. 2, in the wall-hang apparatus using two display device fixtures, there is a specific distance between the two display device fixtures, and the hang limit opening 6 can limit horizontal movement of the display device fixtures to thereby enhance the stability of the display device being installed.

In a technical solution according to an embodiment of the disclosure, the wall fixture is connected on the wall by a fastener, and the display device fixture is connected with the display device body by a fastener. As illustrated in FIG. 1 and FIG. 2, the display device body 7 is fixed to the display device fixture 2 through the bolt 5.

The display device body is installed using the wall-hang apparatus illustrated in FIG. 1 particularly in the following steps:

Firstly the display device body is fixed to the display device fixture through the fastener;

Secondly the wall fixture is fixed on the wall through the fastener (the first step and the second step can be performed in a reversed order);

Thirdly the display device fixture is hung on the wall fixture; and

Fourthly the bolt is inserted into the pin holes.

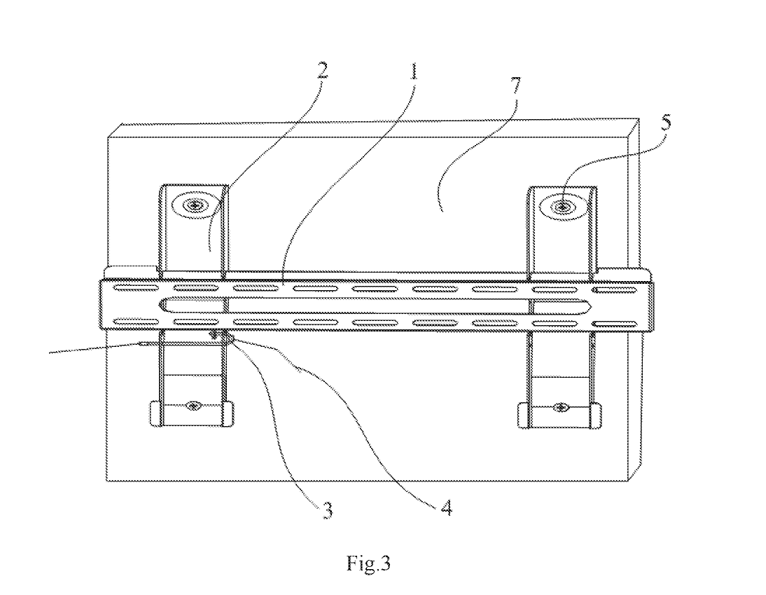

FIG. 3 illustrates the wall-hang apparatus on which the display device body is installed.

An embodiment of the disclosure further provides a display device. The display device includes a display device body, and the wall-hang apparatus according to any one of the technical solutions above. The displaying device body using the wall-hang apparatus will not fall down easily from the wall-hang apparatus even if an external force is applied thereto, so the display device can be installed highly reliably.

Lastly it shall be noted that the respective embodiments above are merely intended to illustrate but not to limit the technical solution of the disclosure; and although the disclosure has been described above in details with reference to the embodiments above, those ordinarily skilled in the art shall appreciate that they can modify the technical solution recited in the respective embodiments above or make equivalent substitutions to a part of the technical features thereof; and these modifications or substitutions to the corresponding technical solution shall also fall into the scope of the disclosure as claimed.

What is claimed is:

1. A wall-hang apparatus of a display device, comprising: a wall fixture fixed to a wall, a display device fixture fixed to a display device body, and a bolt, wherein:
the display device fixture is hung on the wall fixture; and
the wall fixture is provided with a first pin hole, the display device fixture is provided with a second pin hole positioned opposite to the first pin hole, and the bolt is inserted into the first pin hole and the second pin hole.

2. The wall-hang apparatus of a display device according to claim 1, wherein the bolt is provided with a bolt neck, and a bolt head and a bolt tail, both of which are parallel to each other, and connected by the bolt neck.

3. The wall-hang apparatus of a display device according to claim 2, wherein a bolt pull rope is fixed on the bolt tail and the bolt neck of the bolt.

4. The wall-hang apparatus of a display device according to claim 1, wherein the wall fixture is arranged horizontally, and the display device fixture is arranged vertically.

5. The wall-hang apparatus of a display device according to claim 4, wherein the number of display device fixtures is at least two; and the number of bolts is the same as the number of display device fixtures, and each of the bolts is arranged to one corresponding display device fixture.

6. The wall-hang apparatus of a display device according to claim 5, wherein the wall fixture is provided with a hang plate, and each of the display device fixtures is provided with a hang hook hung on the hang plate.

7. The wall-hang apparatus of a display device according to claim 6, wherein the hang plate is provided with a hang limit opening in which the hang hook is hung.

8. A display device, comprising a display device body, and a wall-hang apparatus of a display device,
wherein the wall-hang apparatus comprises a wall fixture fixed to a wall, a display device fixture fixed to a display device body, and a bolt, wherein:
the display device fixture is hung on the wall fixture; and
the wall fixture is provided with a first pin hole, the display device fixture is provided with a second pin hole positioned opposite to the first pin hole, and the bolt is inserted into the first pin hole and the second pin hole.

9. The display device according to claim 8, wherein the bolt is provided with a bolt neck, and a bolt head and a bolt tail, both of which are parallel to each other, and connected by the bolt neck.

10. The display device according to claim 9, wherein a boll pull rope is fixed on the bolt tail and the bolt neck of the bolt.

11. The display device according to claim 8, wherein the wall fixture is arranged horizontally, and the display device fixture is arranged vertically.

12. The display device according to claim 11, wherein the number of display device fixtures is at least two; and the number of bolts is the same as the number of display device fixtures, and each of the bolts is arranged to one corresponding display device fixture.

13. The display device according to claim 12, wherein the wall fixture is provided with a hang plate, and each of the display device fixtures is provided with a hang hook hung on the hang plate.

14. The display device according to claim 13, wherein the hang plate is provided with a hang limit opening in which the hang hook is hung.
